(19) United States
(12) Patent Application Publication
(10) Pub. No.: US 2026/0172028 A1
(43) Pub. Date: Jun. 18, 2026

(54) RADIO FREQUENCY SWITCH DRIVER

(71) Applicant: BeRex Corporation Co., Ltd, Seoul (KR)

(72) Inventors: Yang Hun YUN, Seoul (KR); Tae Won JUNG, Seoul (KR)

(73) Assignee: BeRex Corporation Co., Ltd, Seoul (KR)

(21) Appl. No.: 19/183,192

(22) Filed: Apr. 18, 2025

(30) Foreign Application Priority Data
Dec. 17, 2024 (KR) 10-2024-0187914

(51) Int. Cl. H03K 17/687

(52) U.S. Cl. CPC H03K 17/6872

(57) ABSTRACT

In a radio frequency switch driver, in the case of a circuit in which RF performance is significantly enhanced by using a high control voltage, in order to address performance degradation of a switch driver which may occur, it is possible to prevent performance degradation of a transistor by connecting a resistor in parallel between a drain and a source of the transistor so that equal voltage distribution is ensured between series-connected transistors. The present disclosure may provide stability maintenance of a switch driver circuit, transistor performance protection, electrical characteristics improvement, leakage current reduction, voltage stabilization, power loss mitigation, electromagnetic interference reduction, and output node stabilization. The present disclosure has the effect of assisting an operation of the transistor by connecting a resistor in parallel between the drain and the source of the transistor, thereby enhancing electrical stability, reducing electromagnetic interference (EMI) and improving the quality of an output signal.

### BACKGROUND

### Field

The present disclosure relates to a radio frequency switch driver, and more particularly, to a radio frequency switch driver which, in the case of a circuit in which RF performance is significantly enhanced by using a high control voltage, in order to address performance degradation of a switch driver which may occur, prevents performance degradation of a transistor by connecting a resistor in parallel between a drain and a source of the transistor so that equal voltage distribution is ensured between series-connected transistors.

### Description of the Related Art

In recent years, in order to expand the data bandwidth of communication networks, advanced communication systems in which new methods and frequencies are used have been developed, and in order to process these in a single terminal, many RF switches are being used to separate and process each frequency band and communication method in a front end connected to an antenna.

Although silicon on insulator (SOI) complementary metal-oxide-semiconductor (CMOS) radio frequency (RF) switches are widely used for such RF switches due to their various advantages, it may be advantageous to use higher control voltages for high power driving capability and low insertion loss. SOI CMOS RF switches are powered using a CMOS switch driver.

CMOS switch drivers have a problem in that the transistors react sensitively when there is a momentary change in the control voltage level, causing permanent performance degradation of transistors.

### DOCUMENTS IN RELATED ART

### Patent Documents

(Patent Document 1) Korean Patent Registration No. 10-1075690

### SUMMARY

In order to solve such matters, the present disclosure is directed to providing a radio frequency switch driver which may prevent performance degradation of the transistor by connecting a resistor in parallel between a drain and a source of a transistor so that equal voltage distribution occurs between series-connected transistors to address performance degradation of a switch driver which may occur in a circuit which significantly enhances RF performance by using a high control voltage.

In a radio frequency switch driver according to the characteristics of the present disclosure to achieve the above purpose,
a first P-channel field effect transistor (PFET) and a second PFET may be connected in series, a third N-channel field effect transistor (NFET) and a fourth NFET may be connected in series, and a drain of the second PFET and a drain of the third NFET may be connected, and then an output signal may be output to a connection point in which the second drain of the second PFET and the third drain of the third NFET are connected, and the first PFET, the second PFET, the third NFET, and the fourth NFET each may have a first resistor, a second resistor, a third resistor, and a fourth resistor individually connected between their sources and drains.

In the radio frequency switch driver, a first drain of the first PFET may be connected in series with a second source of the second PFET, a third source of the third NFET may be connected in series with a fourth drain of the fourth NFET, and an output signal may be output to a connection point in which a second drain of the second PFET is connected with a third drain of the third NFET, and
the first PFET may have a first resistor connected between the first source and the first drain, the second PFET may have a second resistor connected between the second source and the second drain, the third NFET may have a third resistor connected between the third drain and the third source, and the fourth NFET may have a fourth resistor connected between the fourth drain and the fourth source.

With the above-described configuration, the present disclosure has the effect of preventing performance degradation of the transistor and improving the stability of the switch driver by connecting a resistor in parallel between the drain and the source of the transistor so that equal voltage distribution occurs between the series-connected transistors.

The present disclosure may provide stability maintenance of a switch driver circuit, transistor performance protection, electrical characteristics improvement, leakage current reduction, voltage stabilization, power loss mitigation, electromagnetic interference reduction, and output node stabilization.

The present disclosure has the effect of assisting an operation of the transistor by connecting a resistor in parallel between the drain and the source of the transistor, thereby enhancing electrical stability, reducing electromagnetic interference (EMI) and improving the quality of an output signal.

### BRIEF DESCRIPTION OF THE DRAWINGS

FIG. 1 is a diagram showing a configuration of a radio frequency switch driver according to an embodiment of the present disclosure.

FIG. 2 is a diagram showing a voltage of each node of a switch driver when an external control voltage Vsw is High according to an embodiment of the present disclosure.

FIG. 3 is a diagram showing a voltage of each node of a switch driver when an external control voltage Vsw is Low according to an embodiment of the present disclosure.

FIG. 4 is a diagram showing an example in which a switch driver according to the related art is used.

FIG. 5 is a diagram showing an example in which a switch driver according to an embodiment of the present disclosure is used.

### DETAILED DESCRIPTION

Embodiments disclosed in this specification will be described in detail below with reference to the attached drawings. Regardless of the drawing symbols, identical or similar constituent elements will be denoted by the same reference numerals and redundant descriptions thereof will be omitted. In addition, when describing the embodiments disclosed in this specification, if it is determined that a detailed description of a related known technique may obscure the gist of the embodiments disclosed in this specification, the detailed description thereof is omitted.

Although terms including ordinal numbers such as first, second, and the like may be used to describe various constituent elements, the constituent elements are not limited by the terms. The above terms are used solely to distinguish one constituent element from another.

Singular expressions include plural expressions unless the context clearly indicates otherwise.

In this application, each step to be described may be performed regardless of the listed order, except in cases in which it needs to be performed in the listed order due to a special causal relationship.

In this application, it needs to be understood that terms such as “comprises,” “includes,” or “has” are intended to specify the presence of a feature, number, step, operation, constituent element, part or combination thereof described in the specification, but do not exclude in advance the possibility of the presence or addition of one or more other features, numbers, steps, operations, constituent elements, parts or combinations thereof.

A circuit which prevents a voltage between each drain and each source of output transistors of a complementary metal-oxide-semiconductor (CMOS) switch driver from becoming too high is required. For this purpose, equal distribution of the drain and source voltages of the output transistors which is connected in series is essential. The present disclosure may connect a resistor having a large resistance value in parallel between the drain and the source of each of the output transistors which is connected in series so that, even if there is a momentary change in the control voltage, the change is distributed evenly to two of the transistors, thereby minimizing the resulting performance degradation.

A radio frequency switch driver of the present disclosure will be described below with reference to the attached drawings.

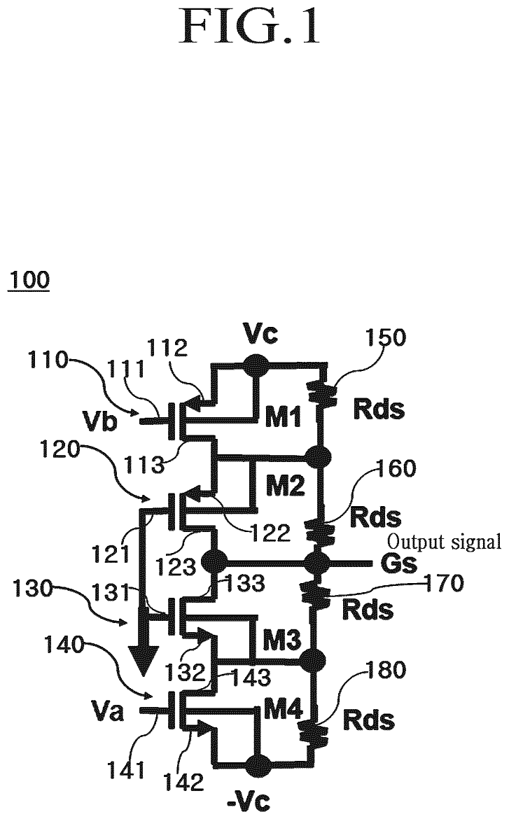

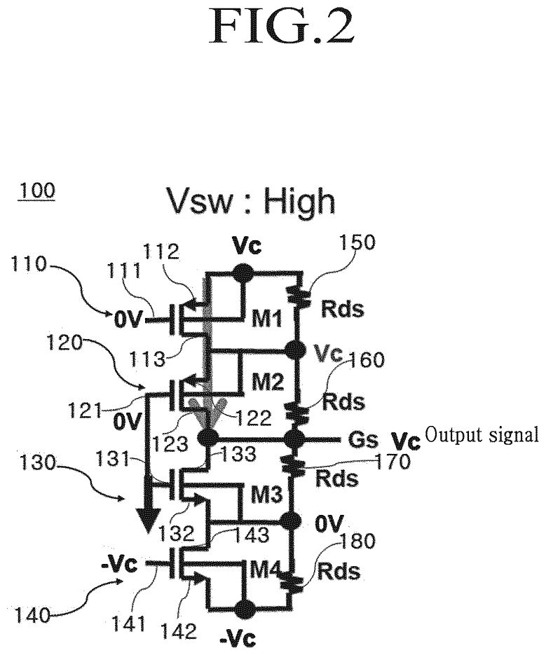

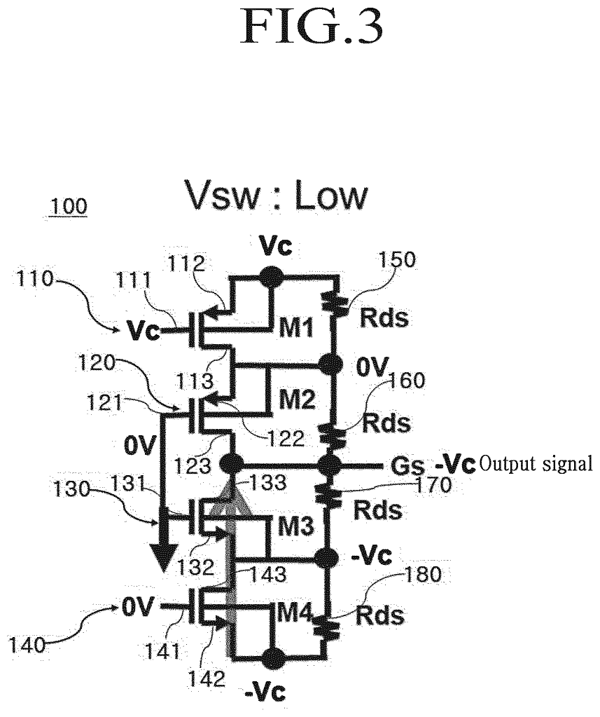

FIG. 1 is a diagram showing a configuration of a radio frequency switch driver according to an embodiment of the present disclosure, FIG. 2 is a diagram showing a voltage of each node of a switch driver when an external control voltage Vsw is High according to an embodiment of the present disclosure, and FIG. 3 is a diagram showing a voltage of each node of a switch driver when an external control voltage Vsw is Low according to an embodiment of the present disclosure.

An N-channel field effect transistor (NFET) and a P-channel field effect transistor (PFET) may be switching and amplifying devices designed on the basis of N-type and P-type semiconductors, respectively.

In an NFET, a current flows from a source S to a drain D and a flow may be controlled through a voltage applied to a gate G. In the NFET, when a positive voltage in which Vgs>0 is satisfied is applied to the gate, a channel is formed and a current flows. In the NFET, electrons flow from the source to the drain through an N-type channel when the drain and source voltage Vds satisfies Vds>0.

In a PFET, a current flows from a drain D to a source S and a flow may be controlled through a voltage applied to a gate G. In the PFET, when a negative voltage in which Vgs<0 is satisfied is applied to the gate, a channel is formed and a current flows. In the PFET, holes flow from the source to the drain through a P-type channel when the drain and source voltage Vds satisfies Vds<0.

The NFET is turned on when a positive voltage is applied to the gate and the PFET is turned on when a negative voltage is applied to the gate. By using such characteristics, PFETs and NFETs may be used complementarily to achieve an efficient and low-power operation in CMOS circuits.

A first PFET 110 may include a first gate 111 which controls a channel by applying a voltage, a first source 112 through which a current flows out, and a first drain 113 through which a current flows in. A positive control voltage is connected to the first source 112 of the first PFET 110.

A second PFET 120 may include a second gate 121 which controls a channel by applying a voltage, a second source 122 through which a current flows out, and a first drain 113 through which a current flows in. The second PFET 120 has a second source 122 connected to the first drain 113 of the first PFET 110.

A third NFET 130 may include a third gate 131 which controls a channel by applying a voltage, a third drain 133 through which a current flows out, and a third source 132 through which a current flows in. The third NFET 130 has a third drain 133 connected to a second drain 123 of the second PFET 120.

A fourth NFET 140 may include a fourth gate 141 which controls a channel by applying a voltage, a fourth drain 143 through which a current flows out, and a fourth source 142 through which a current flows in. The fourth NFET 140 has a fourth drain 143 connected to the third source 132 of the third NFET 130. A negative control voltage is connected to a fourth source 142 of the fourth NFET 140.

A radio frequency switch driver 100 may have a first P-channel field effect transistor (PFET) and the second PFET 120 which are connected in series, a third N-channel field effect transistor (NFET) and the fourth NFET 140 which are connected in series, and the drain of the second PFET 120 and the drain of the third NFET 130 which are connected, and then output an output signal to a connection point in which the second drain 123 of the second PFET 120 and the third drain 133 of the third NFET 130 are connected.

The first PFET 110, the second PFET 120, the third NFET 130, and the fourth NFET 140 may have a first resistor 150, a second resistor 160, a third resistor 170, and a fourth resistor 180 individually connected between their sources and drains, respectively.

By connecting a resistor Rds having a large value in parallel to output ends of the first PFET 110, the second PFET 120, the third NFET 130, and the fourth NFET 140, it is possible to prevent performance degradation of the transistors and improve the stability of the radio frequency switch driver.

A control voltage is a voltage signal used for controlling a specific operation (for example, switching, signal modulation, output adjustment, or the like) in a circuit or a system. The control voltage may be used for determining an operation state (on, off) in a transistor.

The control voltage determines a state of the transistor to regulate an output signal, which may increase the efficiency and reliability of the circuit.

The first PFET 110 may connect the first resistor 150 having a large value between the first source 112 and the first drain 113.

The second PFET 120 may connect the second resistor 160 having a large value between the second source 122 and the second drain 123.

The third NFET 130 may connect the third resistor 170 having a large value between the third drain 133 and the third source 132.

The fourth NFET 140 may connect the fourth resistor 180 having a large value between the fourth drain 143 and the fourth source 142.

The first resistor 150, the second resistor 160, the third resistor 170, and the fourth resistor 180 are individually connected between the sources and the drains of the transistors (the first PFET 110, the second PFET 120, the third NFET 130, and the fourth NFET 140).

Thus, the radio frequency switch driver 100 is formed to have a structure in which the transistors (the first PFET 110, the second PFET 120, the third NFET 130, and the fourth NFET 140) and the resistors are connected in parallel.

The parallel connection structure may maintain the stability of the output node by providing a leakage current path through the resistor when the transistor is in an off state.

Since the parallel connection structure has a large sufficient resistance to be ignored when the transistor is in an on state, it does not directly affect the operation of the transistor.

Since the radio frequency switch driver 100 has a resistor connected between the source and the drain of each of the transistors, the resistors are not directly connected to each other. The resistors are connected in parallel with each transistor and each of the transistors and the resistors may operate independently throughout the circuit. This parallel connection may increase the stability and reliability of the transistor, suppress a leakage current, and improve the output signal quality.

The reason for connecting the first resistor 150, the second resistor 160, the third resistor 170, and the fourth resistor 180 is to maintain the stability of the switch driver circuit, protect the performance of the transistor, improve the electrical characteristics, reduce a leakage current, stabilize a voltage, alleviate power loss, reduce electromagnetic interference, and provide stabilization of the output node.

Leakage current reduction, when the transistor is in an off state, a small amount of current (leakage current) may flow between the source and the drain. A resistor having a large value may provide a path between the source and the drain to suppress the leakage current and improve the output signal quality.

Voltage stabilization may stabilize the transient state by allowing the resistor to smooth out the voltage when the voltage between the source and the drain of the transistor changes abruptly (for example, during switching). This may contribute to the protection and the stable operation of the transistor.

Power loss mitigation may reduce power loss and suppress heat generation by mitigating current spikes which may occur during switching operations if large-value resistors are used.

Electromagnetic interference (EMI) reduction may maintain the signal quality and the reliability of the circuit by providing the resistor absorb or suppress EMI generated during high-speed switching.

Output node stabilization may reduce signal distortion and improve output signal quality by stabilizing the voltage of the output node.

The large values of the first resistor 150, the second resistor 160, the third resistor 170, and the fourth resistor 180 may vary in accordance with the operating conditions of the circuit and the characteristics of the transistor, but may generally be in the megaohm (MΩ) unit. 1 MΩ to 10 MΩ is a commonly used large value resistance range, which may sufficiently suppress a leakage current while preventing excessive voltage drop.

10 MΩ or higher are used in high-impedance circuits having very small currents and may be suitable for circuits which has low switching frequencies or in which maintaining a fixed voltage is important.

The criteria for selecting the resistance value are to adjust a resistance value in accordance with a maximum allowable voltage and leakage current characteristics of the transistor. In addition, a higher resistance value is suitable for a high-speed switching circuit and a higher switching frequency may be used for alleviating transient conditions.

Radio frequency (RF) circuits require resistances of several MΩ or higher for EMI reduction and stability, while direct current (DC) circuits typically have resistances of 1 MΩ to 10 MΩ.

When the first gate 111 has a negative voltage compared to the first source 112, the first PFET 110 is in an on state and a positive control voltage is transferred to the second PFET 120.

When the first PFET 110 is in an off state, the positive control voltage may be blocked.

The second PFET 120 may have an on state or an off state in accordance with a voltage transmitted from the first PFET 110.

When the second PFET 120 is in an on state, a positive control voltage is output to the output signal.

The fourth NFET 140 is in an on state when the fourth gate 141 has a positive voltage compared to the fourth source 142 and a negative control voltage is transmitted to the third NFET 130.

When the fourth NFET 140 is in an off state, the negative control voltage may be blocked.

The third NFET 130 may have an on state or an off state in accordance with a voltage transmitted from the fourth NFET 140.

When the third NFET 130 is in an on state, a negative control voltage is output to the output signal.

When the first PFET 110 and the second PFET 120 are in an on state and the third NFET 130 and the fourth NFET 140 are an off state, the output signal indicates a positive control voltage.

When the third NFET 130 and the fourth NFET 140 are in an on state and the first PFET 110 and the second PFET 120 are in an off state, the output signal indicates a negative control voltage.

A driving signal of an RF switch may be used for the output signal to select or block an RF signal path. The output signal may be generated at a connection point between the second drain 123 of the second PFET 120 and the third drain 133 of the third NFET 130.

The radio frequency switch driver 100 provides accurate and reliable switching using positive control voltages and negative control voltages and may minimize power consumption through complementary operation of the NFET and the PFET.

The first PFET 110 may supply a voltage Vb of the first gate 111 to the first gate 111 and the fourth NFET 140 may supply a voltage Va of the second gate to the fourth gate 141.

The radio frequency switch driver 100 may generate the Va and Vb signals in accordance with an external control voltage Vsw. When the external control voltage Vsw is High, Vb=0 V is satisfied, Va=−Vc is applied, and an output signal Vc is output. At this time, a voltage of 2×Vc is distributed between the drain and the source of the third NFET 130 and the fourth NFET 140 connected in series.

When the external control voltage Vsw is Low, Vb=Vc is satisfied, Va=0 V is applied, and an output signal −Vc is output. At this time, a voltage of 2×Vc is distributed between the drain and the source of the first PFET 110 and the second PFET 120 connected in series.

When the external control voltage Vsw is High, the gate voltage becomes Vb=0 V and Va=−Vc. When Vb=0 V is satisfied, a voltage between the first gate 111 and the first source 112 of the first PFET 110 is a negative voltage −Vc and the first PFET 110 is in an on state. When Va=−Vc is satisfied, a voltage between the fourth gate 141 and the fourth source 142 of the fourth NFET 140 is 0 V and the fourth NFET 140 is in an off state.

In this case, the operation of the transistors is explained as follows.

The first PFET 110 is in an on state when a voltage between the first gate 111 and the first source 112 is −Vc and transfers a positive voltage Vc from the first PFET 110 to the second PFET 120.

The second PFET 120 is in an on state due to Vc transmitted from the first PFET 110 and the output signal Vc is output.

The third NFET 130 has a voltage between the third gate 131 and the third source 132 being 0 V and is in an off state when and a current does not flow.

The fourth NFET 140 has a voltage between the fourth gate (141) and the fourth source (142) being 0 V and is in an off state and a current does not flow.

When the external control voltage Vsw is Low, the gate voltage becomes Vb=Vc and Va=0V. When Vb=Vc is satisfied, a voltage between the first gate 111 and the first source 112 of the first PFET 110 is 0V and the first PFET 110 is in an off state. When Va=0V is satisfied, a voltage between the fourth gate 141 and the fourth source 142 of the fourth NFET 140 is −Vc and the fourth NFET 140 is in an on state.

In this case, the operation of the transistors is explained as follows.

The first PFET 110 has a voltage between the first gate 111 and the first source 112 being 0 V and is in an off state and a current does not flow.

The second PFET 120 is in an off state because the first PFET 110 is in an off state and a current does not flow.

The third NFET 130 has a voltage between the third gate 131 and the third source 132 being −Vc and is in an on state and a current flows from the third source 132 to the third drain 133 with the voltage transferred from the fourth NFET 140.

The fourth NFET 140 has a voltage between the fourth gate 141 and the fourth source 142 being −Vc, is in an on state and transmits a negative voltage −Vc as an output signal.

The first and second gate voltages Vb and Va may determine the switching operations of the fourth NFET 140 and the first PFET 110, respectively. The first and second gate voltages Vb and Va may determine the output signal Vc or −Vc in accordance with the states of the fourth NFET 140 and the first PFET 110.

The first and second gate voltages Vb and Va are generated in accordance with an external control voltage Vsw and the output signal may be switched to Vc or −Vc.

The first and second gate voltages Vb and Va may provide appropriate voltage levels to ensure that the transistor operates in the exact on and off states.

The first and second gate voltages Vb and Va may be designed to minimize power loss which occurs by the transistor during the switching operation.

The first and second gate voltages Vb and Va may be designed to minimize power loss which occurs by the transistor during the switching operation.

The first resistor 150, the second resistor 160, the third resistor 170, and the fourth resistor 180 function as parallel resistors Rds so that, even when the transistor is in an off state, a small current flows through the resistors Rds, allowing the circuit to operate stably.

The first resistor 150, the second resistor 160, the third resistor 170, and the fourth resistor 180 serve to reduce a leakage current and ensure stability of the output signal, improve a switching speed, and assist in charging and discharging of the gate to increase switching speed, and reduce electromagnetic interference (EMI) and the parallel resistors may alleviate high-frequency noise in the circuit to increase stability.

The external control voltage Vsw may be used as an input signal to generate the gate voltages Vb and Va of the first PFET 110 and the fourth NFET 140 in the radio frequency switch driver 100.

When the external control voltage Vsw is High, Vb=0 V and Va=−Vc are satisfied, and when the external control voltage Vsw is Low, Vb=Vc and Va=0 V are satisfied. The external control voltage Vsw may be a main control signal which operates to switch the output signal of the radio frequency switch driver 100 to Vc or −Vc. The external control voltage Vsw is converted into Vb and Va through a logic circuit or a level shifter inside the radio frequency switch driver 100.

The external control voltage Vsw is not directly input to the gates of the transistors (the first PFET 110, the second PFET 120, the third NFET 130, and the fourth NFET 140). The radio frequency switch driver 100 generates Vb and Va in accordance with a state of the external control voltage Vsw and Vb and Va are transmitted to the first gate 111 of the first PFET 110 and the fourth gate 141 of the fourth NFET 140, respectively, to control the operation of the transistors.

The radio frequency switch driver 100 converts a control signal of an external control voltage Vsw into Vb or Va to determine an operation state of the transistors (the first PFET 110, the second PFET 120, the third NFET 130, and the fourth NFET 140), thereby converting the output signal to a desired voltage.

The radio frequency switch driver 100 converts a single control signal of an external control voltage Vsw into a complementary signal Vb or Va to appropriately control transistors (the first PFET 110, the second PFET 120, the third NFET 130, and the fourth NFET 140) and may ensure accuracy and reliability of output signals in circuits requiring a high-speed operation such as RF switches.

The radio frequency switch driver 100 assists the operation of the transistor through parallel resistors (the first resistor 150, the second resistor 160, the third resistor 170, and the fourth resistor 180) to increase electrical stability, reduce EMI (electromagnetic interference), and improve the quality of the output signal.

The radio frequency switch driver 100 controls a state of the transistor in accordance with a state of the external control voltage Vsw to switch the output signal to Vc or −Vc and supports a high-speed operation and power efficiency and enhances stability.

High-voltage silicon on insulator (SOI) CMOS RF switches may be used for selecting or blocking a path of radio frequency signals.

The switch driver for high-voltage SOI CMOS RF switch control is based on an SOI CMOS technique, providing operational stability in high-frequency, high-temperature, and high-voltage environments, accurately generating and outputting high-voltage signals for switching control of RF switches, maintaining RF signal quality through high reliability and stability, and reducing insertion loss and power loss. This switch driver can be an essential component in various high-frequency applications such as high-speed communication systems, RF antenna switching, and high-voltage RF amplifier control.

The radio frequency switch driver 100 may generate a signal for controlling an RF switch and ensure a stable and reliable switching operation in a high-voltage environment.

The radio frequency switch driver 100 may generate a signal for controlling a high-voltage SOI CMOS RF switch and ensure a stable and reliable switching operation in a high-voltage environment.

The radio frequency switch driver has the effect of preventing transistor performance degradation and ensuring the long-term stability of the circuit by adding a parallel resistor Rds, quickly switching the output signal Vc or −Vc in accordance with the state of the external control voltage Vsw, minimizing signal loss in high-frequency circuits such as RF switches, reducing power consumption through the operation of complementary transistors (the PFET and the NFET), maximizing circuit efficiency, and ensuring high-frequency signal quality by maintaining signal quality, suppressing voltage fluctuations, and reducing EMI.

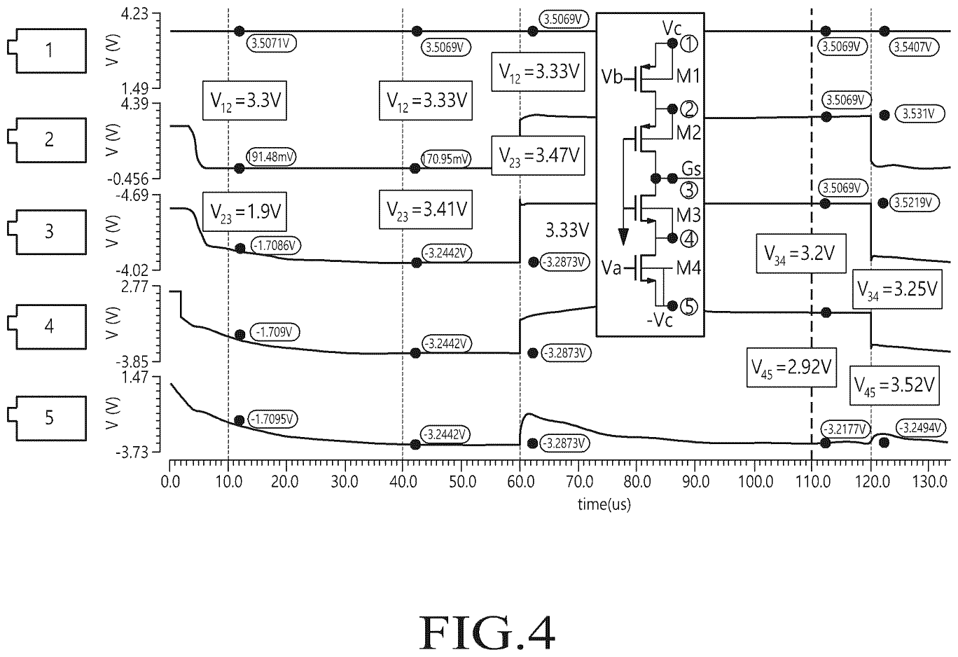

FIG. 4 is a diagram showing an example in which a switch driver according to the related art is used.

The plot is, from the top, a first source of a first PFET 110, a first drain of the first PFET 110, a second source of a second PFET 120, a second drain of the second PFET 120, a third drain of a third NFET, a third source of the third NFET, a fourth drain of a fourth NFET, and a fourth source of the fourth NFET.

An external control voltage Vsw is switching high-low-high at 60 ns and 120 ns. The numbers in the box are a voltages between the drains and the sources of the off-state transistors. As shown in FIG. 4, even after each voltage is stabilized, the two numbers show a significant difference at each stage. The largest difference is 3.2 V−2.92 V=0.28 V.

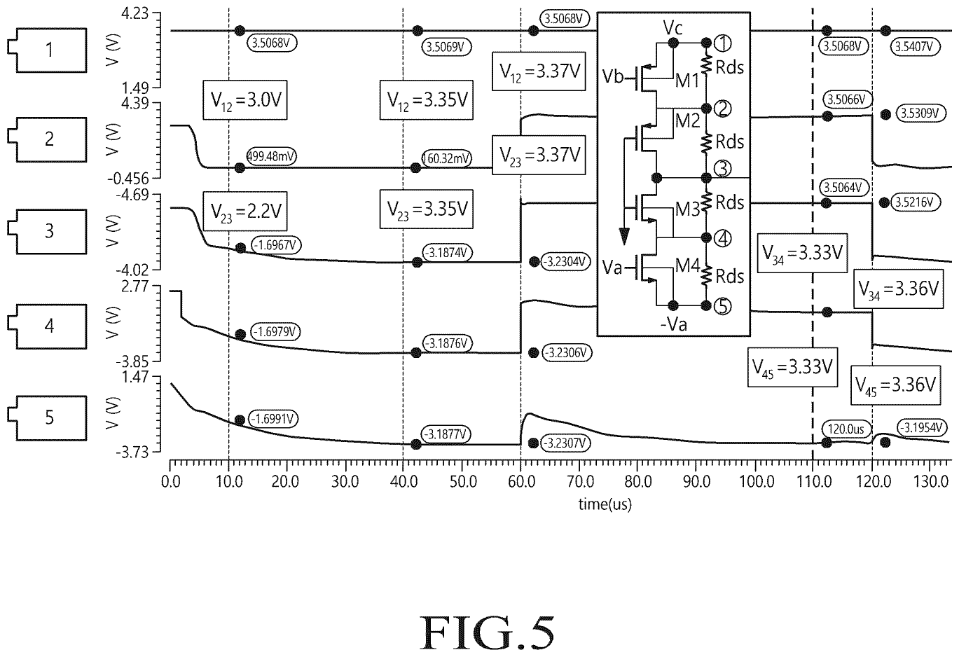

FIG. 5 is a diagram showing an example in which a switch driver according to an embodiment of the present disclosure is used.

The plot is, from the top, a first source of a first PFET 110, a first drain of the first PFET 110, a second source of a second PFET 120, a second drain of the second PFET 120, a third drain of a third NFET, a third source of the third NFET, a fourth drain of a fourth NFET, and a fourth source of the fourth NFET.

The external control voltage Vsw is switching high-low-high at 60 ns and 120 ns. The numbers in the box are the voltages between the drain and the source of the off-state transistors. As shown in FIG. 5, it can be seen that the two numbers match at each stage after each voltage is stabilized.

The present disclosure relates to a circuit implementation for implementing a radio frequency switch having power driving capability and small insertion loss characteristics, and particularly, to preventing performance degradation of a switch driver which may occur in a circuit which significantly improves RF performance by utilizing a high control voltage.

The radio frequency switch driver 100 switches between a positive control voltage Vc and a negative control voltage −Vc at the gate using two transistors connected in series to turn the RF switch on and off. Here, when there is a momentary change in the control voltage Vc, if the voltage distribution between the drain and the source of each transistor is not equal or the bias voltage of all transistor nodes is not defined, a high voltage may be momentarily applied to a specific transistor, which may cause momentary or permanent performance degradation.

At this time, the momentary or permanent performance degradation problem may be improved by connecting resistors having large values (the first resistor 150, the second resistor 160, the third resistor 170, and the fourth resistor 180) in parallel between the drain and the source of each transistor. The reason for using resistors having large values is to minimize current consumption.

The technical features disclosed in each embodiment of the present disclosure are not limited to the embodiment, and unless they are mutually incompatible, the technical features disclosed in each embodiment may be combined and applied to other embodiments.

Therefore, each embodiment will focus on explaining each technical feature, but unless each technical feature is incompatible with each other, it can be applied in combination with each other.

The present disclosure is not limited to the above-described embodiments and the attached drawings and various modifications and variations may be made from the viewpoint of a person having ordinary skill in the art to which the present disclosure belongs. Accordingly, the scope of the present disclosure needs to be determined not only by the claims of this specification but also by equivalents of the claims.

1. A radio frequency switch driver, wherein a first P-channel field effect transistor (PFET) and a second PFET are connected in series, a third N-channel field effect transistor (NFET) and a fourth NFET are connected in series, and a drain of the second PFET and a drain of the third NFET are connected, and then an output signal is output to a connection point in which the second drain of the second PFET and the third drain of the third NFET are connected, and
the first PFET, the second PFET, the third NFET, and the fourth NFET each have a first resistor, a second resistor, a third resistor, and a fourth resistor individually connected between their sources and drains.

2. The radio frequency switch driver of claim 1, wherein a first drain of the first PFET is connected in series with a second source of the second PFET, a third source of the third NFET is connected in series with a fourth drain of the fourth NFET, and an output signal is output to a connection point in which a second drain of the second PFET is connected with a third drain of the third NFET, and
the first PFET has a first resistor connected between the first source and the first drain, the second PFET has a second resistor connected between the second source and the second drain, the third NFET has a third resistor connected between the third drain and the third source, and the fourth NFET has a fourth resistor connected between the fourth drain and the fourth source.

3. The radio frequency switch driver of claim 1, wherein the first source of the first PFET is connected to a positive control voltage Vc and the fourth source of the fourth NFET is connected to a negative control voltage −Vc, and
a first gate voltage Vb is supplied to a first gate of the first PFET and a second gate voltage Va is supplied to a fourth gate of the fourth PFET.

4. The radio frequency switch driver of claim 3, wherein the radio frequency switch driver generates the first gate voltage Vb and the second gate voltage Va in accordance with a state of an external control voltage Vsw and the external control voltage Vsw is converted into the first gate voltage Vb and the second gate voltage Va through a logic circuit or a level shifter in the radio frequency switch driver.

5. The radio frequency switch driver of claim 4, wherein, when the external control voltage Vsw is High, the Vb is 0 V, the Va is −Vc, and an output signal Vc is output, and
when the external control voltage Vsw is Low, Vb is applied to Vc, Va is applied to 0 V, and an output signal −Vc is output.

6. The radio frequency switch driver of claim 2, wherein the first resistor, the second resistor, the third resistor, and the fourth resistor are configured to have a resistance value of 1 MΩ to 10 MΩ and vary in accordance with characteristics of the transistor.
